(19) United States
(12) Patent Application Publication
(10) Pub. No.: US 2013/0061918 A1
(43) Pub. Date: Mar. 14, 2013

(54) PROCESS FOR THE FORMATION OF A SILVER BACK ELECTRODE OF A PASSIVATED EMITTER AND REAR CONTACT SILICON SOLAR CELL

(71) Applicants: Kenneth Warren Hang, Cary, NC (US); Giovanna Laudisio, Bristol (GB); Alistair Graeme Prince, Bedminster (GB); Rosalynne Sophie Watt, Bristol (GB)

(72) Inventors: Kenneth Warren Hang, Cary, NC (US); Giovanna Laudisio, Bristol (GB); Alistair Graeme Prince, Bedminster (GB); Rosalynne Sophie Watt, Bristol (GB)

(73) Assignee: E. I. DUPONT DE NEMOURS AND COMPANY, Wilmington, DE (US)

(21) Appl. No.: 13/410,555

(22) Filed: Mar. 2, 2012

Related U.S. Application Data
(60) Provisional application No. 61/448,777, filed on Mar. 3, 2011.

(51) Int. Cl. H01L 31/0224; H01L 31/18

(52) U.S. Cl. 136/256; 438/72; 257/E31.124

(57) ABSTRACT

A process for the formation of an electrically conductive silver back electrode of a PERC silicon solar cell comprising the steps:
(1) providing a p-type silicon wafer having on its front-side an n-type emitter with an ARC layer thereon and on its back-side a perforated dielectric passivation layer with local BSF contacts at the places of the perforations,
(2) applying and drying a silver paste to form a silver back electrode pattern connecting the local BSF contacts on the back-side of the silicon wafer, and
(3) firing the dried silver paste, whereby the wafer reaches a peak temperature of 700 to 900° C.,
wherein the silver paste has no or only poor fire-through capability and comprises particulate silver and an organic vehicle.

### FIELD OF THE INVENTION

The present invention is directed to a process for the formation of a silver back electrode of a PERC (passivated emitter and rear contact) silicon solar cell and, respectively, to a process for the production of PERC silicon solar cells comprising said silver back electrode. The present invention is also directed to the respective PERC silicon solar cells.

### TECHNICAL BACKGROUND OF THE INVENTION

Typically, silicon solar cells have both front- and back-side metallizations (front and back electrodes). A conventional silicon solar cell structure with a p-type base uses a negative electrode to contact the front-side or sun side of the cell, and a positive electrode on the back-side. It is well known that radiation of an appropriate wavelength falling on a p-n junction of a semiconductor body serves as a source of external energy to generate electron-hole pairs in that body. The potential difference that exists at a p-n junction, causes holes and electrons to move across the junction in opposite directions, thereby giving rise to flow of an electric current that is capable of delivering power to an external circuit. Most solar cells are in the form of a silicon wafer that has been metallized, i.e., provided with metal contacts which are electrically conductive.

The majority of the solar cells currently produced are based upon crystalline silicon. A popular method for depositing electrodes is the screen printing of metal pastes.

PERC silicon solar cells are well-known to the skilled person; see, for example, P. Choulat et al., “Above 17% industrial type PERC Solar Cell on thin Multi-Crystalline Silicon Substrate”, 22^{nd} European Photovoltaic Solar Energy Conference, 3-7 Sep. 2007, Milan, Italy. PERC silicon solar cells represent a special type of conventional silicon solar cells; they are distinguished by having a dielectric passivation layer on their front- and on their back-side. The passivation layer on the front-side serves as an ARC (antireflective coating) layer, as is conventional for silicon solar cells. The dielectric passivation layer on the back-side is perforated; it serves to extend charge carrier lifetime and as a result thereof improves light conversion efficiency. It is desired to avoid damage of the perforated dielectric back-side passivation layer as much as possible.

Similar to the production of a conventional silicon solar cell, the production of a PERC silicon solar cell typically starts with a p-type silicon substrate in the form of a silicon wafer on which an n-type diffusion layer (n-type emitter) of the reverse conductivity type is formed by the thermal diffusion of phosphorus (P) or the like. Phosphorus oxychloride (POCl₃) is commonly used as the gaseous phosphorus diffusion source, other liquid sources are phosphoric acid and the like. In the absence of any particular modification, the n-type diffusion layer is formed over the entire surface of the silicon substrate. The p-n junction is formed where the concentration of the p-type dopant equals the concentration of the n-type dopant. The cells having the p-n junction close to the sun side, have a junction depth between 0.05 and 0.5 μm.

After formation of this diffusion layer excess surface glass is removed from the rest of the surfaces by etching by an acid such as hydrofluoric acid.

Next, a dielectric layer, for example, of TiOₓ, SiOₓ, TiOₓ/SiOₓ, SiNₓ or, in particular, a dielectric stack of SiNₓ/SiOₓ is formed on the front-side n-type diffusion layer. As a specific feature of the PERC silicon solar cell, the dielectric is also deposited on the back-side of the silicon wafer to a thickness of, for example, between 0.05 and 0.1 μm. Deposition of the dielectric may be performed, for example, using a process such as plasma CVD (chemical vapor deposition) in the presence of hydrogen or sputtering. Such a layer serves as both an ARC and passivation layer for the front-side and as a dielectric passivation layer for the back-side of the PERC silicon solar cell. The passivation layer on the back-side of the PERC silicon solar cell is then perforated. The perforations are typically produced by acid etching or laser drilling and the holes so produced are, for example, 50 to 300 μm in diameter. Their depth corresponds to the thickness of the passivation layer or may even slightly exceed it. The number of the perforations lies in the range of, for example, 100 to 500 per square centimeter.

Just like a conventional solar cell structure with a p-type base and a front-side n-type emitter, PERC silicon solar cells typically have a negative electrode on their front-side and a positive electrode on their back-side. The negative electrode is typically applied as a grid by screen printing and drying a front-side silver paste (front electrode forming silver paste) on the ARC layer on the front-side of the cell. The front-side grid electrode is typically screen printed in a so-called H pattern which comprises thin parallel finger lines (collector lines) and two busbars intersecting the finger lines at right angle. In addition, a back-side silver or silver/aluminum paste and an aluminum paste are applied, typically screen printed, and successively dried on the perforated passivation layer on the back-side of the p-type silicon substrate. Normally, the back-side silver or silver/aluminum paste is applied onto the back-side perforated passivation layer first to form anodic back contacts, for example, as two parallel busbars or as rectangles or tabs ready for soldering interconnection strings (presoldered copper ribbons). The back-side aluminum paste is then applied in the bare areas with a slight overlap over the back-side silver or silver/aluminum. In some cases, the back-side silver or silver/aluminum paste is applied after the back-side aluminum paste has been applied. Firing is then typically carried out in a belt furnace for a period of 1 to 5 minutes with the wafer reaching a peak temperature in the range of 700 to 900° C. The front electrode and the back electrodes can be fired sequentially or cofired.

The back-side aluminum paste is generally screen printed and dried on the perforated dielectric passivation layer on the back-side of the silicon wafer. The wafer is fired at a temperature above the melting point of aluminum to form an aluminum-silicon melt at the local contacts between the aluminum and the silicon, i.e. at those parts of the silicon wafer's back-surface not covered by the dielectric passivation layer or, in other words, at the places of the perforations. The so-formed local p+ contacts are generally called local BSF (back surface field) contacts. The back-side aluminum paste is transformed by firing from a dried state to an aluminum back electrode, whereas the back-side silver or silver/aluminum paste becomes a silver or silver/aluminum back electrode upon firing. Typically, back-side aluminum paste and back-side silver or silver/aluminum paste are cofired, although sequential firing is also possible. During firing, the boundary between the back-side aluminum and the back-side silver or silver/aluminum assumes an alloy state, and is connected electrically as well. The aluminum electrode accounts for most areas of the back electrode. The silver or silver/aluminum back electrode is formed over portions of the back-side as an anode for interconnecting solar cells by means of pre-soldered copper ribbon or the like. In addition, the front-side silver paste printed as front-side cathode etches and penetrates through the ARC layer during firing, and is thereby able to electrically contact the n-type layer. This type of process is generally called “firing through”.

### SUMMARY OF THE INVENTION

The present invention relates to a process for the formation of an electrically conductive silver back electrode of a PERC silicon solar cell. Accordingly, it relates also to a process for the production of the PERC silicon solar cell comprising said electrically conductive silver back electrode and the PERC silicon solar cell itself.

The process for the formation of the electrically conductive silver back electrode of a PERC silicon solar cell comprises the steps:
(1) providing a p-type silicon wafer having on its front-side an n-type emitter with an ARC layer thereon and on its back-side a perforated dielectric passivation layer with local BSF contacts at the places of the perforations,
(2) applying and drying a silver paste to form a silver back electrode pattern connecting the local BSF contacts on the back-side of the silicon wafer, and
(3) firing the dried silver paste, whereby the wafer reaches a peak temperature of 700 to 900° C.,
wherein the silver paste has no or only poor fire-through capability and comprises particulate silver and an organic vehicle.

The term “silver paste” is used herein. It shall mean a thick film conductive silver composition comprising particulate silver either as the only or as the predominant electrically conductive particulate metal.

The term “silver back electrode pattern” is used herein. It shall mean the arrangement of a silver back anode on the back-side of a PERC solar cell silicon wafer. This arrangement is characterized by the silver back electrode forming a pattern of fine lines connecting all local BSF contacts. Examples include an arrangement of parallel but connected fine lines connecting all local BSF contacts or a grid of fine lines connecting all local BSF contacts. In case of such grid, it is typically, but not necessarily, a checkered grid. Main point is that the silver back electrode pattern is a pattern which connects all local BSF contacts and thus also guarantees electrical connection of the latter. The silver back electrode pattern is in electrical contact with one or more anodic back contacts ready for soldering interconnection strings like, for example, presoldered copper ribbons. The anodic back contact(s) may take the form of one or more busbars, rectangles or tabs, for example. The anodic back contact(s) itself/themselves may form part of the silver back electrode pattern and may simultaneously be applied together with the fine lines during step (2) of the process of the present invention, i.e. from the same silver paste like the fine lines. It is also possible to apply the anodic back contacts separately, i.e. before or after application of the fine lines which connect all local BSF contacts.

In the present description and the claims the term “fire-through capability” is used. It shall mean the ability of a metal paste to etch and penetrate through (fire through) a passivation or ARC layer during firing. In other words, a metal paste with fire-through capability is one that fires through a passivation or an ARC layer making electrical contact with the surface of the silicon substrate. Correspondingly, a metal paste with poor or even no fire through capability makes no electrical contact with the silicon substrate upon firing. To avoid misunderstandings; in this context the term “no electrical contact” shall not be understood absolute; rather, it shall mean that the contact resistivity between fired metal paste and silicon surface exceeds 1 Ω·cm², whereas, in case of electrical contact, the contact resistivity between fired metal paste and silicon surface is in the range of 1 to 10 mΩ·m².

The contact resistivity can be measured by TLM (transfer length method). To this end, the following procedure of sample preparation and measurement may be used: A silicon wafer having an ARC or passivation layer (for example, a 75 nm thick SiNₓ layer) is screen printed on that layer with the metal paste to be tested in a pattern of parallel lines (for example, 127 μm wide and 6 μm thick lines with a spacing of 2.2 mm between the lines) and is then fired with the wafer reaching a peak temperature of, for example, 800° C. The fired wafer is laser-cutted into 10 mm by 28 mm long strips, where the parallel lines do not touch each other and at least 6 lines are included. The strips are then subject to conventional TLM measurement at 20° C. in the dark. The TLM measurement can be carried out using the device GP 4-Test Pro from GP Solar.

### DETAILED DESCRIPTION OF THE INVENTION

It has been found that the process of the present invention allows for the production of PERC silicon solar cells with improved electrical efficiency. The fired silver paste adheres well to the back-side passivation layer and thus gives rise to a long durability or service life of the PERC silicon solar cells produced by the process of the present invention.

Without being bound to theory it is believed that the silver paste used in the process of the present invention for the production of the silver back electrode does not or not significantly damage the dielectric passivation layer on the silicon wafer's back-side during firing.

The process of the present invention allows to form a silver back electrode of a PERC silicon solar cell which is free of an aluminum back anode and where a back-side aluminum paste has been applied and fired just locally at those places where local BSF contacts are desired. The process of the present invention allows for a maximum of local BSF contacts since the entire area of the silicon wafer's back-side can be used for the local BSF contacts and no area portions need to be reserved for conventional anodic silver back contacts.

In step (1) of the process of the present invention a p-type silicon wafer having a front-side n-type emitter with an ARC layer thereon and with a back-side perforated dielectric passivation layer with local BSF contacts at the places of the perforations is provided. To avoid misunderstandings; even though the silicon wafer has local BSF contacts it has no aluminum back electrode. The silicon wafer is a mono- or polycrystalline silicon wafer as is conventionally used for the production of silicon solar cells; it has a p-type region, an n-type region and a p-n junction. The silicon wafer has an ARC layer on its front-side n-type emitter and a perforated dielectric passivation layer on its back-side, both layers, for example, of TiOₓ, SiOₓ, TiOₓ/SiOₓ, SiNₓ or, in particular, a dielectric stack of SiNₓ/SiOₓ. Such silicon wafers are well known to the skilled person; for brevity reasons reference is expressly made to the section “TECHNICAL BACKGROUND OF THE INVENTION”.

At the places of the perforations of the back-side dielectric passivation layer there are local BSF contacts.

In an embodiment, said perforations and local BSF contacts can be formed in one step. To this end, an aluminum paste having fire-through capability is applied on the not yet perforated back-side dielectric passivation layer of the p-type silicon wafer to form a pattern of local BSF contacts and subsequently fired. During firing the aluminum paste etches and penetrates through the dielectric passivation layer thus forming the perforations and allowing local contacts between the aluminum and the silicon. Firing is carried out at a temperature above the melting point of aluminum to form an aluminum-silicon melt at the local contacts between the aluminum and the silicon, i.e., at the places of the perforations.

The term “pattern of local BSF contacts” is used herein. It means the arrangement of the local BSF contacts in terms of size and distance between the individual local BSF contacts. As already mentioned above, the perforations are, for example, 50 to 300 μm in diameter and their depth corresponds to the thickness of the back-side passivation layer or may even slightly exceed it. The number of the perforations lies in the range of, for example, 100 to 500 per square centimeter.

In another and preferred embodiment, the local BSF contacts are formed in a different manner. Here, a p-type silicon wafer having a front-side n-type emitter with an ARC layer thereon and an already perforated back-side dielectric passivation layer is provided. As already mentioned in the section “TECHNICAL BACKGROUND OF THE INVENTION”, the perforations are typically produced by acid etching or laser drilling. An aluminum paste, in particular but not necessarily, an aluminum paste having no or only poor fire-through capability is printed at the places of the perforations and subsequently fired. The aluminum contacts the silicon at the bottom of the perforations and during firing at a temperature above the melting point of aluminum an aluminum-silicon melt is formed at the local contacts between the aluminum and the silicon with the final result of formation of a pattern of local BSF contacts.

The silicon wafer may already be provided with the conventional front-side metallizations, i.e. with front-side silver paste as described above in the section “TECHNICAL BACKGROUND OF THE INVENTION”. Application of the front-side metallization may be carried out before or after the silver back electrode is finished. To avoid misunderstandings, the front-side silver paste differs from the silver paste used for forming the silver back electrode; the front-side silver paste has fire-through capability.

In step (2) of the process of the present invention a silver paste is applied to form a silver back electrode pattern connecting the local BSF contacts on the back-side of the silicon wafer. The silver paste has no or only poor fire-through capability and comprises particulate silver and an organic vehicle.

In a particular embodiment of the process of the present invention, the silver paste comprises at least one glass frit selected from the group consisting of (i) lead-free glass frits with a softening point temperature in the range of 550 to 611° C. and containing 11 to 33 wt.-% (weight-%) of SiO₂, >0 to 7 wt.-%, in particular 5 to 6 wt.-% of Al₂O₃ and 2 to 10 wt.-% of B₂O₃ and (ii) lead-containing glass frits with a softening point temperature in the range of 571 to 636° C. and containing 53 to 57 wt.-% of PbO, 25 to 29 wt.-% of SiO₂, 2 to 6 wt.-% of Al₂O₃ and 6 to 9 wt.-% of B₂O₃.

The term “softening point temperature” is used herein. It shall mean the glass transition temperature, determined by differential thermal analysis DTA at a heating rate of 10 K/min.

The particulate silver may be comprised of silver or a silver alloy with one or more other metals like, for example, copper. In case of silver alloys the silver content is, for example, 99.7 to below 100 wt.-%. In an embodiment, the particulate silver is silver powder. The silver powder may be uncoated or at least partially coated with a surfactant. The surfactant may be selected from, but is not limited to, stearic acid, palmitic acid, lauric acid, oleic acid, capric acid, myristic acid and linolic acid and salts thereof, for example, ammonium, sodium or potassium salts. The silver powder exhibits an average particle size of, for example, 0.5 to 5 μm. The particulate silver may be present in the silver paste in a proportion of 50 to 92 wt.-%, or, in an embodiment, 65 to 84 wt.-%, based on total silver paste composition.

The term “average particle size” is used herein. It shall mean the average particle size (mean particle diameter, d50) determined by means of laser scattering.

All statements made herein in relation to average particle sizes relate to average particle sizes of the relevant materials as are present in the silver paste composition.

The particulate silver present in the silver paste may be accompanied by a small amount of one or more other particulate metals or particulate silicon. Examples of other particulate metals include copper powder, palladium powder, nickel powder, chromium powder and, in particular, aluminum powder. In an embodiment, the silver paste is free of other particulate metal(s) and particulate silicon. In another embodiment, the particulate metal content of the silver paste comprises 95 to 99 wt.-% of particulate silver and 1 to 5 wt.-% of particulate aluminum.

The silver paste comprises an organic vehicle. A wide variety of inert viscous materials can be used as organic vehicle. The organic vehicle may be one in which the particulate constituents (particulate silver, optionally present other particulate metals, optionally present particulate silicon, glass frit, further optionally present inorganic particulate constituents) are dispersible with an adequate degree of stability. The properties, in particular, the rheological properties, of the organic vehicle may be such that they lend good application properties to the silver paste composition, including: stable dispersion of insoluble solids, appropriate viscosity and thixotropy for application, appropriate wettability of the silicon wafer's passivated back-side and the paste solids, a good drying rate, and good firing properties. The organic vehicle used in the silver paste may be a nonaqueous inert liquid. The organic vehicle may be an organic solvent or an organic solvent mixture; in an embodiment, the organic vehicle may be a solution of organic polymer(s) in organic solvent(s). In an embodiment, the polymer used for this purpose may be ethyl cellulose. Other examples of polymers which may be used alone or in combination include ethylhydroxyethyl cellulose, wood rosin, phenolic resins and poly(meth)acrylates of lower alcohols. Examples of suitable organic solvents comprise ester alcohols and terpenes such as alpha- or beta-terpineol or mixtures thereof with other solvents such as kerosene, dibutylphthalate, diethylene glycol butyl ether, diethylene glycol butyl ether acetate, hexylene glycol and high boiling alcohols. In addition, volatile organic solvents for promoting rapid hardening after application of the silver paste on the silicon wafer's back-side can be included in the organic vehicle. Various combinations of these and other solvents may be formulated to obtain the viscosity and volatility requirements desired.

The organic vehicle content in the silver paste may be dependent on the method of applying the paste and the kind of organic vehicle used, and it can vary. In an embodiment, it may be from 20 to 45 wt.-%, or, in an embodiment, it may be in the range of 22 to 35 wt.-%, based on total silver paste composition. The number of 20 to 45 wt.-% includes organic solvent(s), possible organic polymer(s) and possible organic additive(s).

The organic solvent content in the silver paste may be in the range of 5 to 25 wt.-%, or, in an embodiment, 10 to 20 wt.-%, based on total silver paste composition.

The organic polymer(s) may be present in the organic vehicle in a proportion in the range of 0 to 20 wt.-%, or, in an embodiment, 5 to 10 wt.-%, based on total silver paste composition.

In the particular embodiment of the process of the present invention, the silver paste comprises at least one glass frit selected from the group consisting of (i) lead-free glass frits with a softening point temperature in the range of 550 to 611° C. and containing 11 to 33 wt.-% of SiO₂, >0 to 7 wt.-%, in particular 5 to 6 wt.-% of Al₂O₃ and 2 to 10 wt.-% of B₂O₃ and (ii) lead-containing glass frits with a softening point temperature in the range of 571 to 636° C. and containing 53 to 57 wt.-% of PbO, 25 to 29 wt.-% of SiO₂, 2 to 6 wt.-% of Al₂O₃ and 6 to 9 wt.-% of B₂O₃.

In case of the lead-free glass frits of type (i), the weight percentages of SiO₂, Al₂O₃ and B₂O₃ do not total 100 wt.-% and the missing wt.-% are in particular contributed by one or more other oxides, for example, alkali metal oxides like Na₂O, alkaline earth metal oxides like MgO and metal oxides like Bi₂O₃, TiO₂ and ZnO.

The lead-free glass frits of type (i) may contain 40 to 73 wt.-%, in particular 48 to 73 wt.-% of Bi₂O₃. The weight percentages of Bi₂O₃, SiO₂, Al₂O₃ and B₂O₃ may or may not total 100 wt.-%. In case they do not total 100 wt.-% the missing wt.-% may in particular be contributed by one or more other oxides, for example, alkali metal oxides like Na₂O, alkaline earth metal oxides like MgO and metal oxides like TiO₂ and ZnO.

In case of the lead-containing glass frits of type (ii), the weight percentages of PbO, SiO₂, Al₂O₃ and B₂O₃ may or may not total 100 wt.-%. In case they do not total 100 wt.-% the missing wt.-% may in particular be contributed by one or more other oxides, for example, alkali metal oxides like Na₂O, alkaline earth metal oxides like MgO and metal oxides like TiO₂ and ZnO.

In case the silver paste used in the particular embodiment of the process of the present invention comprises lead-free glass frit of type (i) as well as lead-containing glass frit of type (ii), the ratio between both glass frit types may be any or, in other words, in the range of from >0 to infinity. Generally, the silver paste as used in the particular embodiment of the process of the present invention comprises no glass frit other than glass frit selected from the group consisting of types (i) and (ii).

The one or more glass frits selected from the group consisting of types (i) and (ii) serve as inorganic binder. The average particle size of the glass frit(s) is in the range of, for example, 0.5 to 4 μm. The total content of glass frit selected from the group consisting of types (i) and (ii) in the silver paste as used in the particular embodiment of the process of the present invention is, for example, 0.25 to 8 wt.-%, or, in an embodiment, 0.8 to 3.5 wt.-%.

The preparation of the glass frits is well known and consists, for example, in melting together the constituents of the glass, in particular in the form of the oxides of the constituents, and pouring such molten composition into water to form the frit. As is well known in the art, heating may be conducted to a peak temperature in the range of, for example, 1050 to 1250° C. and for a time such that the melt becomes entirely liquid and homogeneous, typically, 0.5 to 1.5 hours.

The glass may be milled in a ball mill with water or inert low viscosity, low boiling point organic liquid to reduce the particle size of the frit and to obtain a frit of substantially uniform size. It may then be settled in water or said organic liquid to separate fines and the supernatant fluid containing the fines may be removed. Other methods of classification may be used as well.

The silver paste may comprise one or more organic additives, for example, surfactants, thickeners, rheology modifiers and stabilizers. The organic additive(s) may be part of the organic vehicle. However, it is also possible to add the organic additive(s) separately when preparing the silver paste. The organic additive(s) may be present in the silver paste in a total proportion of, for example, 0 to 10 wt.-%, based on total silver paste composition.

The silver paste applied in step (2) of the process of the present invention is a viscous composition, which may be prepared by mechanically mixing the particulate silver and the glass frit(s) with the organic vehicle. In an embodiment, the manufacturing method power mixing, a dispersion technique that is equivalent to the traditional roll milling, may be used; roll milling or other mixing technique can also be used.

The silver paste can be used as such or may be diluted, for example, by the addition of additional organic solvent(s); accordingly, the weight percentage of all the other constituents of the silver paste may be decreased.

As already mentioned, the silver paste is applied in a silver back electrode pattern on the silicon wafer's back-side. The silver paste is applied to a dry film thickness of, for example, 5 to 30 μm and with a line width of, for example, 50 to 150 μm. The method of silver paste application may be printing, for example, silicone pad printing or, in an embodiment, screen printing.

The application viscosity of the silver paste may be 20 to 400 Pa·s when it is measured at a spindle speed of 10 rpm and 25° C. by a utility cup using a Brookfield HBT viscometer and #14 spindle.

After application, the silver paste is dried, for example, for a period of 1 to 100 minutes with the silicon wafer reaching a peak temperature in the range of 100 to 300° C. Drying can be carried out making use of, for example, belt, rotary or stationary driers, in particular, IR (infrared) belt driers.

In step (3) of the process of the present invention the dried silver paste is fired to form a silver back electrode. The firing of step (3) may be performed, for example, for a period of 1 to 5 minutes with the silicon wafer reaching a peak temperature in the range of 700 to 900° C. The firing can be carried out making use of, for example, single or multi-zone belt furnaces, in particular, multi-zone IR belt furnaces. The firing may happen in an inert gas atmosphere or in the presence of oxygen, for example, in the presence of air. During firing the organic substance including non-volatile organic material and the organic portion not evaporated during the drying may be removed, i.e. burned and/or carbonized, in particular, burned. The organic substance removed during firing includes organic solvent(s), optionally present organic polymer(s) and optionally present organic additive(s). At least in case of the particular embodiment of the process of the present invention there is a further process taking place during firing, namely sintering of glass frit with the particulate silver. During firing the silver paste does not fire through the back-side perforated passivation layer, but it contacts the local BSF contacts.

Firing may be performed as so-called cofiring together with front-side metal pastes, for example, front-side silver pastes that have been applied to the PERC solar cell silicon wafer to form front metal electrodes. In an embodiment, the cofiring may be performed together with a back-side aluminum paste which has been applied to form local BSF contacts.

### EXAMPLES

The following examples illustrate the determination of the fire-through capability of silver pastes. The examples show also the adhesion between fired silver paste and a substrate with a passivation layer of SiNx. The adhesion test and the fire-through test were carried out making use of a conventional sample p-type base silicon cell with an n-type emitter and a 75 nm thick SiNₓ ARC layer on the wafer's emitter applied by CVD. It is believed that the properties here measured are not affected by the type of substrate (n-type or p-type) but only by the presence of the SiNx passivation layer.

### (1) Manufacture of Test Samples

### (i) Silver Pastes 1 to 3:

The compositions of the silver pastes 1 to 3 are displayed in Table 1. The pastes comprise of silver powder (average particle size 2 μm), organic vehicle (polymeric resins and organic solvents) and glass frit (average particle size 8 μm). Table 2 provides composition data of the glass frit type employed.

TABLE 1

| Silver | Composition (wt.-%) | | |
|---|---|---|---|
| Paste | silver powder | organic vehicle | glass frit type |
| 1 | 85.0 | 14.5 | 0.5 of type 1 |
| 2 | 81.0 | 17.0 | 2.0 of type 1 |
| 3 | 86.0 | 9.3 | 4.7 of type 2 |

TABLE 2

| | Softening | | | | | | | |
|---|---|---|---|---|---|---|---|---|
| | point | | | | | | | |
| Glass | temperature | Glass components (wt.-%) | | | | | | |
| type | (° C.) | SiO₂ | Al₂O₃ | B₂O₃ | PbO | TiO₂ | ZrO₂ | Li₂O |
| 1 | 573 | 28 | 4.7 | 8.1 | 55.9 | 3.3 | — | — |
| 2 | 438 | 17.8 | 0.2 | 1.9 | 79.5 | — | 0.5 | 0.1 |

### (ii) Formation of TLM Samples:

On the front face of Si substrates (200 μm thick multicrystalline silicon wafers of area 243 cm², p-type (boron) bulk silicon, with an n-type diffused POCl₃ emitter, surface texturized with acid, 75 nm thick SiNₓ ARC layer on the wafer's emitter applied by CVD) having a 30 μm thick aluminum electrode (screen-printed from PV381 Al composition commercially available from E. I. Du Pont de Nemours and Company) the silver pastes 1-3 were screen-printed as 127 μm wide and 6 μm thick parallel finger lines having a distance of 2.2 mm between each other. The aluminum paste and the silver paste were dried before cofiring.

The printed wafers were then fired in a Despatch furnace at a belt speed of 3000 mm/min with zone temperatures defined as zone 1=500° C., zone 2=525° C., zone 3=550° C., zone 4=600° C., zone 5=925° C. and the final zone set at 890° C., thus the wafers reaching a peak temperature of 800° C.

To produce TLM samples, the fired wafers were subsequently laser scribed and fractured into 10 mm×28 mm TLM samples, where the parallel silver metallization lines did not touch each other. Laser scribing was performed using a 1064nm infrared laser supplied by Optek.

(iii) Formation of Samples for Adhesion Measurements:

On the front face of Si substrates (200 μm thick multicrystalline silicon wafers of area 243 cm², p-type (boron) bulk silicon, with an n-type diffused POCl₃ emitter, surface texturized with acid, 75 nm thick SiNx ARC layer on the wafer's emitter applied by CVD) the silver pastes 1-3 were screen-printed and dried as 2 mm wide and 25 μm thick busbars.

The printed wafers were then fired in a Despatch furnace at a belt speed of 3000 mm/min with zone temperatures defined as zone 1=500° C., zone 2=525° C., zone 3=550° C., zone 4=600° C., zone 5=925° C. and the final zone set at 890° C., thus the wafers reaching a peak temperature of 800° C.

### (2) Test Procedures and Results

### (i) TLM Measurement:

The TLM samples were measured by placing them into a GP 4-Test Pro instrument available from GP Solar for the purpose of measuring contact resistivity. The measurements were performed at 20° C. with the samples in darkness. The test probes of the apparatus made contact with 6 adjacent fine line silver electrodes of the TLM samples, and the contact resistivity (ρc) was recorded.

### (ii) Fired Adhesion Measurement:

For the adhesion test, a commercially available automated solder machine from Semtek (PV Soldering Machine, Model SCB-160) was employed. The solder process involved coating a solder ribbon (62Sn-36Pb-2Ag) with flux (Kester 952S) and applying the force of 10 heated pins to the coated solder ribbon and busbar to induce wetting of the fired silver surface on the silicon substrate, resulting in adhesion between the busbar and ribbon. The heated pins were set to a temperature of 260° C. and the soldering pre-heat plate where the sample of interest was placed was set to 180° C.

Adhesion was measured pulling on the solder ribbon at multiple points along the bus bar at speed of 100 mm/s and angle of 90°. The force to remove the busbar was measured in Newtons (N).

Table 3 presents the measured contact resistivity and average adhesion data.

TABLE 3

| | | Contact | | |
|---|---|---|---|---|
| | | Resistivity | | Average |
| Example | Silver paste | (Ω · cm²) | | Adhesion (N) |
| 1 (reference | 1 | >364 | Ω · cm²*⁾ | 5.1 ± 1.6 |
| example) | | | | |
| 2 (reference | 2 | >364 | Ω · cm²*⁾ | 4.8 ± 1.1 |
| example) | | | | |
| 3 (comparative | 3 | 1.9 | mΩ · cm² | 3.1 ± 1.2 |
| example) | | | | |

*⁾The contact resistivity exceeded the upper measurable limit for the GP 4-Test Pro equipment (>364 Ω · cm²).

What is claimed is:

1. A process for the formation of an electrically conductive silver back electrode of a PERC silicon solar cell comprising the steps:
(1) providing a p-type silicon wafer having on its front-side an n-type emitter with an ARC layer thereon and on its back-side a perforated dielectric passivation layer with local BSF contacts at the places of the perforations,
(2) applying and drying a silver paste to form a silver back electrode pattern connecting the local BSF contacts on the back-side of the silicon wafer, and
(3) firing the dried silver paste, whereby the wafer reaches a peak temperature of 700 to 900° C.,
wherein the silver paste has no or only poor fire-through capability and comprises particulate silver and an organic vehicle.

2. The process of claim 1, wherein the silver paste comprises at least one glass frit selected from the group consisting of (i) lead-free glass frits with a softening point temperature in the range of 550 to 611° C. and containing 11 to 33 wt.-% of SiO₂, >0 to 7 wt.-% of Al₂O₃ and 2 to 10 wt.-% of B₂O₃ and (ii) lead-containing glass frits with a softening point temperature in the range of 571 to 636° C. and containing 53 to 57 wt.-% of PbO, 25 to 29 wt.-% of SiO₂, 2 to 6 wt.-% of Al₂O₃ and 6 to 9 wt.-% of B₂O₃.

3. The process of claim 2, wherein one or more of the lead-free glass frits contain 40 to 73 wt.-% of Bi₂O₃.

4. The process of claim 2 or 3, wherein the total content of glass frit selected from the group consisting of types (i) and (ii) in the silver paste is 0.25 to 8 wt.-%.

5. The process of claim 1, wherein the particulate silver is present in a proportion of 50 to 92 wt.-%, based on total silver paste composition.

6. The process of claim 1, wherein the organic vehicle content is from 20 to 45 wt.-%, based on total silver paste composition.

7. The process of claim 1, wherein the silver paste is applied by printing.

8. The process of claim 1, wherein firing is performed as cofiring together with a back-side aluminum paste and/or front-side metal pastes that have been applied to the silicon wafer to form local BSF contacts and/or front metal electrodes.

9. An electrically conductive silver back electrode of a PERC silicon solar cell made by the process of claim 1.

10. A PERC silicon solar cell comprising the electrically conductive silver back electrode of claim 9.
